(19) United States
(12) Patent Application Publication
(10) Pub. No.: US 2020/0124928 A1
(43) Pub. Date: Apr. 23, 2020

(54) METHOD FOR CORRECTING DEFECT, DEFECT CORRECTION APPARATUS, AND DISPLAY PANEL

(71) Applicant: SAKAI DISPLAY PRODUCTS CORPORATION, Sakai-shi, Osaka (JP)

(72) Inventor: SHINJI MATSUZAKI, Sakai-shi, Osaka (JP)

(21) Appl. No.: 16/490,042

(22) PCT Filed: Mar. 9, 2017
(86) PCT No.: PCT/JP2017/009550

§ 371 Date: Oct. 21, 2019

(51) Int. Cl. G02F 1/1362; H01L 51/56; G02F 1/13; H01L 27/32; H01L 51/00; G02F 1/1368

(52) U.S. Cl. CPC G02F 1/136259; H01L 51/56; G02F 1/1303; G02F 2001/136268; H01L 27/3244; H01L 51/0031; G02F 1/1368; H01L 27/3223

(57) ABSTRACT

A method for correcting defect with turning a defective pixel into a black point in a display panel (1) comprising a plurality of pixels (10) each comprising a transistor (11, 12). The present method comprises detecting a pixel to be corrected from among the plurality of pixels in the display panel. The present method comprises implanting an ion into a given region corresponding to the transistor in a detected pixel such that the transistor (12) does not turn on at a time of display operation of the display panel.

### TECHNICAL FIELD

The present invention relates to a method for correcting defect with turning a defect of a pixel, such as a bright point, in a display panel into a black point to correct the defect, a defect correction apparatus, and a display panel.

### BACKGROUND ART

In a display panel such as an organic-EL panel and a liquid crystal panel, etc., interfusion of a foreign substance, etc., can cause a defect such as a bright point in which the luminance of a pixel is abnormally high to occur. In such a case, a technique is known to turn the defective pixel into a black point in which the luminance of the defective pixel is decreased to correct the defect of the display panel. For example, in the organic-EL panel, the surrounding of a light-emitting region in the pixel being bright point is cut by laser to turn the pixel being bright point into the black point.

Moreover, Patent Document 1 discloses a method for manufacturing a liquid crystal display apparatus, an object of which is to make a bright point defect in a liquid crystal display apparatus invisible. According to the method disclosed in Patent Document 1, a halogen ion and a metal ion are doped into a portion corresponding to the bright point defect in a glass substrate of the liquid crystal display apparatus and irradiating the doped portion with laser. In this way, a light-blocking layer is formed in the glass substrate and light from the bright point defect is blocked to achieve turning of the pixel being bright point into the black point.

### PRIOR ART DOCUMENT

### Patent Document

### Patent Document 1: WO 2009/013921 A

### SUMMARY OF THE INVENTION

### Problem to be Solved by the Invention

An object of the present invention is to provide a method for correcting defect, a defect correction apparatus, and a display panel which make it possible to accurately turn a defect of a pixel in a display panel into a black point.

### Means to Solve the Problem

A method for correcting defect according to one aspect of the present invention is a method for turning a defective pixel into a black point in a display panel comprising a plurality of pixels each comprising a transistor. The present method comprises detecting a pixel to be corrected from among a plurality of pixels in the display panel. The present method comprises implanting an ion into a given region corresponding to a transistor in a detected pixel such that the transistor does not turn on at a time of display operation of the display panel.

A defect correction apparatus according to one aspect of the present invention turns a defective pixel into a black point in a display panel. The defect correction apparatus comprises an information obtaining unit and an ion implantation unit. The information obtaining unit obtains position information indicating a position of a pixel to be corrected from among a plurality of pixels in the display panel. The ion implantation unit implants an ion, based on position information obtained, into a given region corresponding to a transistor in a pixel at a position indicated by the position information such that the transistor does not turn on at a time of display operation of the display panel.

A display panel according to one aspect of the present invention displays an image. The display panel comprises a plurality of pixels each comprising a transistor. The plurality of pixels comprises a pixel inn which concentration of ion in a semiconductor layer between a source and a drain of the transistor is a given value or more. The given value corresponds to a value to which a threshold voltage of the transistor is shifted such that a gate voltage used at a time of display operation of the display panel does not reach the threshold voltage.

### Effects of the Invention

A method for correcting defect, a defect correction apparatus, and a display panel according to the present invention make it possible to accurately turn a defect of a pixel in a display panel into a black point by making a transistor in the pixel to be corrected inoperable with ion implantation.

### BRIEF DESCRIPTION OF THE DRAWINGS

FIG. 1 shows a diagram for describing a display panel according to Embodiment 1 of the present invention.

FIG. 2 shows a cross-sectional view of a pixel structure of a display panel for describing a method for correcting defect.

FIG. 3 shows a block diagram showing a configuration of an inspection system according to Embodiment 1.

FIG. 4 shows a block diagram showing a configuration of an ion implantation apparatus of the inspection system.

### EMBODIMENT FOR CARRYING OUT THE INVENTION

Below, Embodiments of the present invention will be described with reference to the attached drawings. In each of the Embodiments below, the same reference numerals are affixed to the same elements.

### Embodiment 1

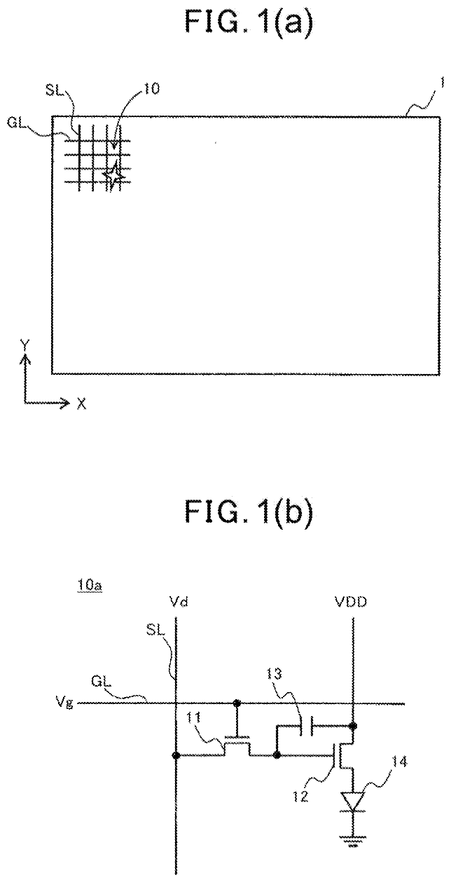

Embodiment 1 of a method for correcting defect of a display panel according to the present invention will be described with reference to FIGS. 1 to 4.

### 1. Method for Correcting Defect

FIG. 1(a) shows a diagram exemplifying a display panel 1 to be an object of a method for correcting defect according to the present embodiment. The present method for correcting defect can apply to a case in which a defect occurs such as a bright point in which a pixel 10 has abnormally high luminance, a blinking point in which the pixel 10 blinks, etc.

The display panel 1 comprises a plurality of pixels 10 arranged in a matrix shape on a display surface, a gate line GL arranged in correspondence with a row in the matrix of pixels 10, and a source line SL arranged in correspondence with a column in the matrix of pixels 10. One of the pixels 10 corresponds to one color of R, G, and B, for example. Below, the direction in which the gate line GL of the display panel 1 extends is referred to as “the X direction” and the direction in which the source line SL of the display panel 1 extends is referred to as “the Y direction”.

In the present embodiment, a case in which the display panel 1 is an organic-EL panel is described. FIG. 1(b) shows one example of an equivalent circuit 10a (referred to as “a pixel circuit” below) of the pixel 10 in the display panel 1 according to the present embodiment.

The pixel circuit 10a exemplified in FIG. 1 comprise two TFTs (thin-film transistors) 11 and 12, one capacitor 13, and an OLED (organic light-emitting diode) 14. In the present example, the two TFTs 11 and 12 are a switching TFT 11 and a drive TFT 12 each consisting of N-type transistor. The gate of the switching TFT 11 is connected to the gate line GL, the source is connected to the source line SL, and the drain is connected to the gate of the drive TFT 12.

The switching TFT 11 functions as a switch to select the pixel 10. Based on a gate signal Vg input from the gate line GL, the switching TFT 11 turns on when the gate voltage is a given threshold voltage or more and turns off when the gate voltage is less than the given threshold voltage.

The drive TFT 12 drives light emission of the OLED 14 based on a power supply voltage VDD. The gate voltage of the drive TFT 12 is controlled based on a data signal Vd input from the source line SL when the switching TFT 11 is on. The drive TFT 12 turns on when the gate voltage is a given threshold value or more and turns off when the gate voltage is less than the given threshold value. The drive TFT 12 in the on state allows current according to the gate voltage to flow into the OLED 14.

The capacitor 13 charges discharges based on the data signal Vd when the switching TFT 11 is on state and holds the gate voltage of the drive TFT 12 when the switching TFT 11 is off state.

The OLED 14 is an example of a light-emitting element comprising an organic material. When the drive TFT 12 is on state, the OLED 14 emits light with an amount of light according to current controlled by the drive TFT 12. Moreover, when the drive TFT 12 is off state, the OLED 14 does not emit light.

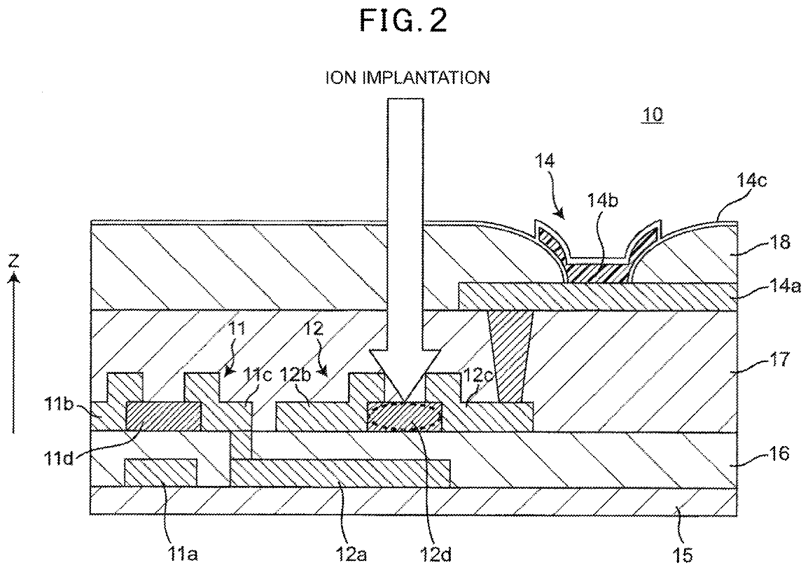

In the present embodiment, when the pixel 10 being, for example, a bright point is detected as a pixel to be corrected in the display panel 1 as described above, the TFT 12 in the pixel 10 to be corrected is caused to be inoperable using local ion implantation. In this way, when the display panel 10 performs display operation displaying various images, the drive TFT 1.2 of the pixel 10 to be corrected does not turn on, causing the OLED 14 to not emit light. Below, with reference to FIG. 2, a method for correcting defect using ion implantation will be described.

FIG. 2 is a cross-sectional view of a pixel structure in the thickness direction of the display panel 1. Below, the thickness direction of the display panel 1 is referred to as “the Z direction”. Moreover; the +Z side can be referred to as “the upper side”, while the −Z side can be referred to as “the lower side”.

As shown in FIG. 2, the switching TFT 11 and the drive TFT 12 are provided on the substrate 15 by laminating various electrodes, a gate insulator 16 and a semiconductor layer, and is covered with a flattening film 17. Along with a bank 18, the OLED 14 is provided on the flattening film 17 on the upper side of the substrate 15.

The switching TFT 11 comprises three electrodes being a gate 11a, a source 11b, and a drain 11c, and a semiconductor layer 11d provided between the source 11b and the drain 11c. The semiconductor layer lid is a N+ layer, for example, and is doped with a donor of a given concentration which is common among the pixels 10. The semiconductor layer lid and the gate 11a face each other via the gate insulator 16 and a channel of the switching TFT 11 is formed at the interface between the semiconductor layer 11d and the gate insulator 16.

The drive TFT 12 comprises three electrodes being a gate 12a, a source 12b, and a drain 12c, and a semiconductor layer 12d provided between the source 12b and the drain 12c. The semiconductor layer 12d of the drive TFT 12 is configured in a manner similar to the semiconductor layer 11d of the switching TFT 11, for example. In a manner similar to the switching TFT 11, a channel of the drive TFT 12 is formed at the interface between the semiconductor layer 12d and the gate insulator 16. The drain 12 c of the drive TFT 12 is connected to an electrode 14a of the OLED 14.

The OLED 14 comprises the electrode 14a, an organic layer 14b, and a cathode 14c. The electrode 14a constitutes the anode of the OLED 14. The organic layer 14b is formed of an organic material having the light-emitting property. The cathode 14c faces the electrode 14a via the organic layer 14b.

In the structure of the pixel 10 such as described above, with the method for correcting defect according to the present embodiment, a positive ion of a trivalent atom such as boron, etc. is implanted into the semiconductor layer 12d of the drive TFT 12. The threshold voltage of a N-type transistor such as the drive TFT 12 increases with an increase in an amount of dosing of the above-described ion in the semiconductor layer 12d between the source 12b and the drain 12c.

Here, the threshold voltage of a normal drive TFT 12 not subjected to the above-described ion implantation is set within a given range which can be set as the gate voltage of the drive TFT 12 at the time of display operation of the display panel 1. With the method for correcting defect according to the present embodiment, ion implantation is executed at an amount of dosing such that the threshold voltage of the drive TFT 12 takes a given value above a maximum value of the gate voltage that can be set at the time of display operation of the display panel 1. In this way, the drive TFT 12 subjected to the ion implantation is always off state at the time of display operation of the display panel 1, and it is possible to accurately turn the pixel 10 to be corrected to a black point.

Moreover, according to the present embodiment, as shown in FIG. 2, ion is implanted from the +Z side of the display panel 1. In this way, energy of ion implantation can be reduced compared to a case in which ion is implanted from the −Z side so as to penetrate the substrate 15.

Moreover, on the display surface (XY plane) of the display panel 1, various elements, such as the drive TFT 12 of each pixel 10 are regularly arranged in a given layout. The given layout is set in dependence on the model of the display panel 1, or R, G, and B of the pixel 10, or the like. According to the present embodiment, layout information indicating a layout of a pixel structure of the display panel 1 is used to accurately identify a region into which ion is to be implanted in the method for correcting defect.

An inspection system for the display panel 1 for carrying out the method for correcting defect as described above will be described below.

### 2. Inspection System

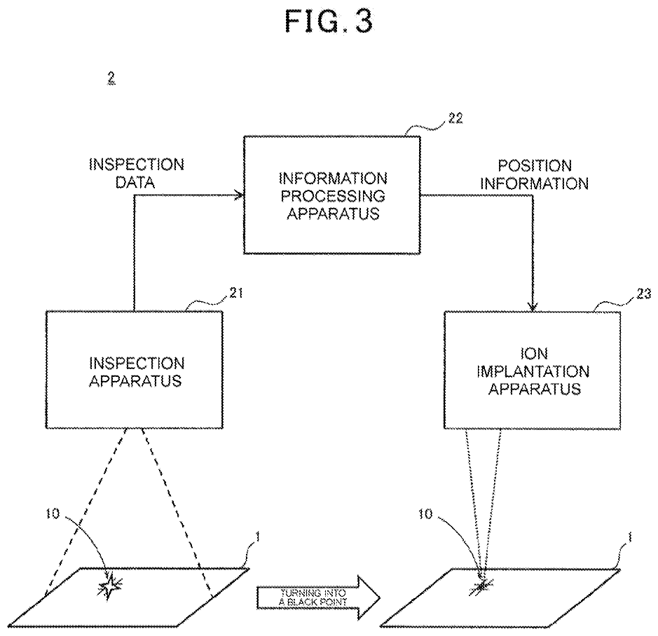

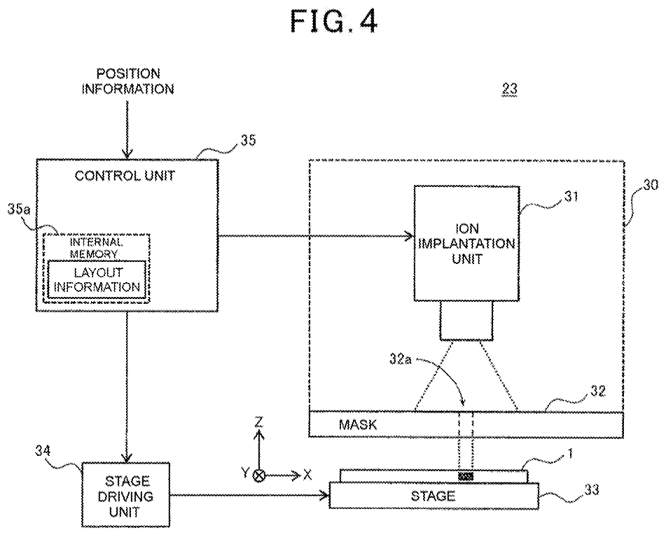

An inspection system for the display panel 1 according to the present Embodiment will be described with reference to FIGS. 3 and 4.

FIG. 3 is a block diagram showing a configuration of an inspection system 2 according to the present embodiment. The inspection system 2 inspects each display panel 1 at the time of manufacturing shipment of a plurality of display panels 1, for example. The inspection system 2 can be used in various inspection steps in the manufacturing steps of the display panel 1.

As shown in FIG. 3, the inspection system 2 comprises an inspection apparatus 21, an information processing apparatus 22, and an ion implantation apparatus 23.

The inspection apparatus 21 is an AOI (Automated Optical Inspection) apparatus, for example. The inspection apparatus 21 comprises a camera to generate a captured image and a CPU, etc., to execute a given image analysis algorithm and conducts an automated optical inspection on each of the display panels 1.

In the automated optical inspection, the inspection apparatus 21 captures the display panel 1 to be inspected and conducts image analysis on the captured image of the display panel 1 for inspecting various defects such as the bright point, blinking point, etc. For example, when there is a pixel 10 being bright point in the display panel 1, the inspection apparatus 21 detects the pixel 10 being bright point based on, for example, the luminance difference within the captured image in the image analysis of the captured image of the display panel 1.

The inspection apparatus 21 generates inspection data indicating results of inspection of the display panel 1 by the image analysis and transmits the generated inspection data to the information processing apparatus 22. If a defective pixel 10 such as a bright point or a blinking point, for example, is detected, the inspection data includes information indicating the detected defect pixel 10 as the pixel to be corrected. The inspection data can include identifying information of the display panel 1 subjected to inspection.

The information processing apparatus 22 executes information processing using a software tool, etc., for managing inspection results of the display panel 1 based on the inspection data from the inspection apparatus 21. The information processing apparatus 22 is a PC (personal computer) or a server apparatus, for example.

The information processing apparatus 22 comprises a memory to store therein programs such as a software tool and various data sets such as the inspection data of the display panel 1 etc., and a CPU to read information stored in the memory to realize given information processing functions, etc. The information processing apparatus 22 is communicatively connected to the inspection apparatus 21 and the ion implantation apparatus 23, etc., via an interface circuit following a given communication protocol.

When the inspection data from the inspection apparatus 21 includes information indicating the pixel 10 detected to be corrected, the information processing apparatus 22 generates position information indicating the position of the pixel 10. The position information includes an X coordinate and a Y coordinate of the center position of the pixel 10 to be corrected in the display panel 1, for example. The information processing apparatus 22 transmits the generated position information to the ion implantation apparatus 23.

The ion implantation apparatus 23, based on the position information from the information processing apparatus 22, locally executes ion implantation to correct the defect by turning the defect into a black point. The ion implantation apparatus 23 is one example of a defect correction apparatus according to the present embodiment. The configuration and operation of the ion implantation apparatus 23 will be described using FIG. 4.

FIG. 4 is a block diagram showing a configuration of the ion implantation apparatus 23 in the inspection system 2. As shown in FIG. 4, the ion implantation apparatus 23 comprises an ion implantation unit 31, a mask 32, a stage 33, a stage driving unit 34, and a control unit 35.

The ion implantation unit 31 comprises an ion source to generate a given ion (for example, boron), an acceleration tube to accelerate the ion generated, a beam emitting unit to emit an ion beam of the accelerated ion, etc. The ion implantation unit 31 and the mask 32 are fixed to a common housing, for example, and integrally configured as a head 30.

In the head 30, the mask 32 is arranged so as to face the beam emitting unit of the ion implantation unit 31. The mask 32 is larger than the display surface of the display panel 1, for example, and comprises a hole (below called “a mask hole”) 32a having a given size. The size of the mask hole 32a corresponds to the size of the semiconductor layer 12d (FIG. 2) of the drive TFT 12 within the pixel 10 on the display surface (XY plane) of the display panel 1, for example. The size of the mask hole 32a can be appropriately set within a range not more than the size of one pixel 10 on the display surface.

The stage 33 is arranged to face the mask 32. According to the present embodiment, the display panel 1 is placed on the stage 33 such that a main surface (display surface) of the display panel 1 faces the mask 32.

The stage driving unit 34 is made up of various type of actuator drivable in two axial directions. The stage driving unit 34 drives the position of the stage 33 along the X and Y directions of the placed display panel 1 by control of the control unit 35.

The control unit 35 comprises a CPU, etc., realizing given functions in cooperation with software, for example, and controls the overall operation of the ion implantation apparatus 23. Moreover, the control unit 35 comprises an interface circuit following the given communication protocol and receives the position information from the information processing apparatus 22. The control unit 35 is one example of an information obtaining unit in the ion implantation apparatus 23.

Moreover, the control unit 35 comprises an internal memory 35a such as a flash memory. The internal memory 35a stores therein given programs, the position information from the information processing apparatus 22, and layout information of the display panel 1, etc., for example. The layout information of the display panel 1 indicates, for example, an arrangement of R, G, and B of the pixel 10 on the display surface of the display panel 1 and an arrangement of various elements in each pixel 10 of R, G, and B.

The control unit 35 reads data and programs stored in the internal memory 35a to perform various arithmetic processing and realizes various functions such as a function of obtaining information from the information processing apparatus 22 and control of ion implantation by the ion implantation apparatus 23. The control unit 35 can be a hardware circuit such as a dedicated electronic circuit designed to realize given functions or a reconfigurable electronic circuit. The control unit 35 can be composed of various type of semiconductor integrated circuit such as a CPU, an MPU, a microcomputer, a DSP, an FPGA, an ASIC, and the like.

An operation of the ion implantation apparatus 23 configured as described above will be described below. In the following, the display panel 1 in which the pixel 10 to be corrected is detected by the inspection apparatus 21 is assumed to be placed on the stage 33 of the ion implantation apparatus 23.

First, the control unit 35 of the ion implantation apparatus 23 obtains the position information from the information processing apparatus 22 and identifies a position on the display panel 1 at which ion implantation is executed.

For example, the control unit 35 identifies which of R, G, and B the pixel 10 to be corrected is based on the layout information stored in the internal memory 35a and the position of the pixel indicated by the position information. Moreover, with reference to the layout information, the control unit 35 adds and/or subtracts X and Y coordinates of the semiconductor layer 12d (FIG. 2) of the drive TFT 12 within the pixel identified to/from the position indicated by the position information to calculate the position at which ion implantation is executed.

Next, the control unit 35 controls the stage driving unit 34 to drive the stage 33 and performs alignment such that the position identified in the display panel 1 on the stage 33 and the position of the mask hole 32a of the mask 32 fixed to the head 30 match.

Next, the control unit 35 controls the ion implantation unit 31 to execute implantation of ion into the display panel 1 on the stage 33. An ion beam is emitted toward the mask 32 from the beam emitting unit of the ion implantation unit 31. The mask 32 blocks any incident ion beam other than the ion beam incident on the mask hole 32a. In this way, the ion beam is irradiated to a region, on the display panel 1, facing the mask hole 32a, and ion is implanted.

The ion implantation unit 31 accelerates ion generated by the ion source to given energy and emits the ion beam. In the present embodiment, the given energy is set such that the ion reaches the semiconductor layer 12d from the +Z side of the display panel 1 (see FIG. 2).

Ion implantation by the ion implantation apparatus 23 is executed until an amount of dosing of ion (in other words, the concentration of the ion) implanted into the semiconductor layer 12d reaches a given value. In order that the gate voltage of the drive TFT 12 that can be set at the time of display operation of the display panel 1 does not reach a threshold voltage of the drive TFT 12, the given value is set to a value (for example, 1×10¹² ions/cm² or more) at which the threshold voltage is shifted.

According to the above-described operation, the ion implantation apparatus 23 can implant ion into the semiconductor layer 12d of the drive TFT 12 of the pixel 10 to be corrected which has been detected by the inspection apparatus 21 based on the position information obtained from the information processing apparatus 22 and it is possible to turn the pixel 10 into a black point accurately.

In the above-described operation, when a plurality of models of display panel 1 is handled by the inspection system 2, for example, the position at which ion implantation is executed can be identified for each model. For example, the layout information for each type of display panel 1 is stored in the internal memory 35a in advance and, when executing ion implantation, the ion implantation apparatus 23 obtains identification information indicating the model of display panel 1 from the information processing apparatus 22, etc., to use the layout information for the model indicated by the identification information.

Moreover, in the above-described operation, a region at which ion implantation is executed on the display panel 1 can be appropriately set within a range including the semiconductor layer 12d (FIG. 2) of the drive TFT 12 of the pixel 10 to be corrected. For example, the entirety of the pixels 10 to be corrected can be set as the region at which the ion implantation is executed.

### 3. Summary

As described above, a method for correcting defect according to the present embodiment is a method to turn a defective pixel 10 into a black point in a display panel 1 comprising a plurality of pixels (10) each comprising TFTs 11, 12. The present method comprises detecting a pixel 10 to be corrected from among the plurality of pixels 10 in the display panel 1. The present method also comprises implanting an ion into a given region corresponding to the drive TFT 12 in the detected pixel 10 such that the drive TFT 12 does not turn on at the time of display operation of the display panel 1.

According to the above-described method, through the ion implantation, it is possible to turn a defect of the pixel 10 in the display panel 1 into a black point accurately by making the drive TFT 12 in the pixel 10 to be corrected inoperable at the time of display operation of the display panel 1.

In the present embodiment, implanting the ion comprises implanting the ion until a threshold voltage of the drive TFT 12 is shifted such that a gate voltage of the drive TFT 12 used at the time of display operation of the display panel 1 does not reach the threshold voltage. In this way, the drive TFT 12 is maintained in an off state at the time of display operation of the display panel 1, and it is possible to improve the accuracy of turning a defect into a black point.

Moreover, in the present embodiment, the given region into which the ion is implanted comprises a semiconductor layer 12d between a source 12b and a drain 12c of the drive TFT 12. In this way, an amount of dosing in the region at which channel of the drive TFT 12 is formed can be varied and it is possible to set the threshold voltage of the drive TFT 12 accurately.

In the present embodiment, detecting the pixel 10 to be corrected comprises detecting a pixel 10 being bright point, or a pixel 10 being blinking point. According to the present method, it is possible to turn a defect of the pixel 10 such as the bright point or the blinking point in the display panel 1 into a black point.

Moreover, in the present embodiment, the display panel 1 is an organic-EL panel. Implanting the ion comprises implanting the ion such that the drive TFT 12 to drive light emission of the pixel 10 in the organic-EL panel does not turn on at the time of display operation of the display panel 1. In this way, it is possible to turn a defect into a black point accurately by causing the OLED 14, through the ion implantation, not to emit light.

Furthermore, in the present embodiment, implanting the ion comprises implanting a boron ion into the drive TFT 1.2 being a N-type transistor. An ion to be implanted into the N-type transistor is not limited to the boron ion and can be a positive ion of other trivalent atoms.

Moreover, in the present embodiment, the ion implantation apparatus 23 is one example of a defect correction apparatus to turn a defective pixel 10 in a display panel 1 into a black point. The ion implantation apparatus 23 comprises the control unit 35 and the ion implantation unit 31. The control unit 35 functions as an information obtaining unit to obtain a position information indicating a position of a pixel 10 to be corrected from among the plurality of pixels 10 in the display panel 1. The ion implantation unit 31 implants an ion, based on the obtained position information, into a given region corresponding to the drive TFT 12 such that the drive TFT 12 in the pixel 10 at the position indicated by the position information does not turn on at the time of display operation of the display panel 1.

According to the above-described ion implantation apparatus 23, through the ion implantation, it is possible to turn a defect of the pixel 10 in the display panel 1 into a black point accurately by making the drive TFT 12 in the pixel 10 to be corrected inoperable at the time of display operation of the display panel 1.

Moreover, according to the present embodiment, a display panel 1 displays an image. The display panel 1 comprises a plurality of pixels 10 each comprising TFTs 11 and 12. When the method for correcting defect is applied to the display panel 1, the plurality of pixels 10 comprises a pixel 10 in which concentration of ion in a semiconductor layer 12d between a source 12b and a drain 12c of the drive TFT 12 is a given value or more. The given value corresponds to a value to which a threshold voltage of the drive TFT 12 is shifted such that a gate voltage, of the drive TFT 12, used at the time of display operation of the display panel 1 does not reach the threshold voltage of the drive TFT 12.

According to the above-described display panel 1, the drive TFT 12 in the specific pixel 10 is to be inoperable at the time of display operation of the display panel 1 so that it is possible to turn the pixel 10 in the display panel 1 into a black point accurately.

### OTHER EMBODIMENTS

While ion is implanted into the semiconductor layer 12d from the +Z side of the display panel 1. (see FIG. 2) according to the above-described. Embodiment 1, ion implantation can be executed from the −Z side of the display panel 1. When the ion implantation is executed from the −Z side, the energy of ion is set in the ion implantation apparatus 23 such that the ion can penetrate the substrate 15 of the display panel 1 to reach the semiconductor layer 12d, for example.

Moreover, while alignment is performed in the ion implantation apparatus 23 by driving the stage 33 in each of the above-described embodiments, it is not limited thereto, so that the head 30 of the ion implantation apparatus 23 can be driven, for example. Furthermore, the mask 32 can be moved independently from the ion implantation unit 31, in which case the ion implantation unit 31 and the mask 32 can be configured so as not to be integrated as the head 30 specially.

Moreover, while the drive TFT 12 in the pixel 10 to be corrected is made inoperable through the ion implantation in each of the Embodiments described above, the present invention is not limited thereto. For example, ion implantation can be performed so as to make the switching TFT 11 inoperable, in addition to the drive TFT 12 or instead of the drive TFT 12.

Moreover, an example in which the two TFTs 11 and 12, being the switching TFT 11 and the drive TFT 12, are included in the pixel 10 has been described in each embodiment described above, when the pixel to be corrected comprises a plurality of transistors, an ion can be implanted so as to make at least any one of the transistors inoperable.

Furthermore, an example in which ion implantation for turning a defect into a black point is executed for an N-type transistor has been described in each embodiment described above, the ion implantation can be executed for a P-type transistor. When the transistor for which the ion implantation is executed is a P-type transistor, a negative ion of a pentavalent atom such as phosphorus or arsenic can be implanted. Even in this case, the ion is implanted until a threshold voltage of the transistor is shifted such that the gate voltage used at the time of display operation of the display panel 1 does not reach the threshold voltage of the transistor. In other words, an amount of dosing in the ion implantation is set so as to be a given value (for example, 1×10¹³ ions/cm² or more) at which a threshold voltage of a target transistor is less than the minimum value of the gate voltage, of the transistor, which can be set at the time of display operation of the display panel 1.

Moreover, while the threshold voltage of the transistor is shifted by ion implantation in each embodiment described above, it is not particularly limited thereto, so that the transistor can be made inoperable by ion implantation according to other principles. For example, the gate and the source of the transistor can be shorted or a part of the transistor can be broken to make the transistor inoperable.

Moreover, while an example in which the display panel 1 is an organic-EL panel has been described in each embodiment described above, the present invention is not limited to the organic-EL panel, so that it can apply to various active matrix-type display panels such as a liquid crystal panel. For example, when a defective pixel in the liquid crystal panel is to be corrected, a TFT included in a pixel of the liquid crystal panel can be made inoperable.

While specific embodiments and variations of the present invention have been described as in the foregoing, the present invention is not limited thereto, so that various changes can be made thereto within the scope of the present invention and executed. For example, the contents of individual embodiments described above can be combined, as needed, to make them one embodiment of the present invention.

1. A method for correcting defect with turning a defective pixel into a black point in a display panel comprising a plurality of pixels each comprising a transistor, the method comprising:
detecting a pixel to be corrected from among a plurality of pixels in the display panel; and
implanting an ion into a given region corresponding to a transistor in a detected pixel such that the transistor does not turn on at a time of display operation of the display panel.

2. The method for correcting defect according to claim 1,
wherein implanting the ion comprises implanting the ion until a threshold voltage of the transistor is shifted such that a gate voltage used at a time of display operation of the display panel does not reach the threshold voltage.

3. The method for correcting defect according to claim 1,
wherein the given region comprises a semiconductor layer between a source and a drain of the transistor.

4. The method for correcting defect according to claim 1,
wherein detecting the pixel to be corrected comprises detecting a pixel being bright point, or a pixel being blinking point.

5. The method for correcting defect according to claim 1,
wherein the display panel is an organic-EL panel.

6. The method for correcting defect according to claim 5,
wherein implanting the ion comprises implanting the ion such that a transistor to drive light emission of a pixel in the organic-EL panel does not turn on at a time of display operation of the display panel.

7. The method for correcting defect according to claim 1,
wherein the display panel is a liquid crystal panel.

8. The method for correcting defect according to claim 1,
wherein implanting the ion comprises implanting any of a boron ion, a phosphorus ion, and an arsenic ion.

9. A defect correction apparatus to turn a defective pixel into a black point in a display panel comprising a plurality of pixels each comprising a transistor, the defect correction apparatus comprising:
an information obtaining unit to obtain position information indicating a position of a pixel to be corrected from among a plurality of pixels in the display panel; and
an ion implantation unit to implant an ion, based on position information obtained, into a given region corresponding to a transistor in a pixel at a position indicated by the position information such that the transistor does not turn on at a time of display operation of the display panel.

10. A display panel to display an image, the display panel comprising:
a plurality of pixels each comprising a transistor,
wherein the plurality of pixels comprises a pixel in which concentration of ion in a semiconductor layer between a source and a drain of the transistor is a given value or more; and
the given value corresponds to a value to which a threshold voltage of the transistor is shifted such that a gate voltage used at a time of display operation of the display panel does not reach the threshold voltage.
